(19) United States
(12) Patent Application Publication
(10) Pub. No.: US 2004/0233740 A1
(43) Pub. Date: Nov. 25, 2004

(54) Semiconductor memory

(75) Inventor: Atsuhiko Shibasaki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/690,698

(22) Filed: Oct. 23, 2003

(30) Foreign Application Priority Data
Apr. 2, 2003 (JP) 2003-099370

(51) Int. Cl. G11C 7/00

(52) U.S. Cl. 365/200

(57) ABSTRACT

A semiconductor memory includes a Y decoder (1) and an X decoder (2). The Y decoder (1) is connected to two bit lines (3, 4), and the X decoder (2) is connected to four word lines (5-8). The drain terminals of flash memory cells (9-16) are respectively connected to one of the bit lines (3, 4). The bit lines (3, 4) are connected to a sense amplifier for detecting variations in voltage (or current) applied to the bit lines (3, 4) at the time of readout. The gate terminals of the flash memory cells (9-16) are respectively connected to one of the word lines (5-8). Further, bit line disconnecting transistors (17, 18) serving as disconnecting devices are provided between the Y decoder (1) and the bit lines (3, 4), respectively. The gate terminals of the bit line disconnecting transistors (17, 18) are connected in common.

### BACKGROUND OF THE INVENTION

1. Field of the Invention

The present invention relates to a semiconductor memory, and more particularly to a semiconductor memory capable of distinguishing between whether an over-erased defective memory cell is present and whether a decoder has a defect.

2. Description of the Background Art

In a semiconductor memory such as a flash memory, a state in which a floating gate is filled with electrons is called a written state, and a state in which electrons have been removed from the floating gate is called an erased state. When such semiconductor memory has foreign matters or defects in cells, erasure may remove too much electrons from the floating gate, resulting in an over-erased defective memory cell.

In a method of reading out a flash memory comprised of applying voltage to a bit line and a word line which correspond to an address, detecting variations in the voltage or current applied to the bit line, and judging a case in which the voltage applied to the bit line decreases or current flows through the bit line as the erased state and a case in which the voltage applied to the bit line does not vary or no current flows through the bit line as the written state, the occurrence of an over-erased defective memory cell in a semiconductor memory causes the voltage applied to the bit line for readout to be removed from the over-erased defective memory cell, and memory cells on the same bit line as the over-erased defective memory cell are all judged to be in the erased state contrary to an expected value. This is because leakage current occurs between the source and drain of the over-erased defective memory cell. Further, the occurrence of such over-erased defective memory cell in the semiconductor memory causes voltage applied to the bit line for writing generated by a charge pump circuit to be removed from the over-erased defective memory cell at the time of writing to memory cells. Then, writing cannot be performed on memory cells on the same bit line as the over-erased defective memory cell.

When a decoder has defects or a charge pump circuit which generates voltage for bringing memory cells into the written state or erased state has defects, similar phenomenon may occur as in the case of the over-erased defective memory cell. This makes it important in failure analysis of a semiconductor memory to distinguish an over-erased defective memory cell from defects in a decoder or charge pump circuit.

Japanese Patent Application Laid-Open No. 9-102199 (1997) (pp. 4-7, FIGS. 1-4) describes a method of reading a non-volatile memory array for minimizing leakage current in an over-erased defective memory cell, but it does not describe a configuration of a semiconductor memory cell for distinguishing such over-erased defective memory cell from defects in a decoder or charge pump circuit nor a method thereof.

Distinguishing an over-erased defective memory cell from other defects is important in failure analysis. This is because taking measures without identifying defects will not bring about the effect of improvement since measures to be taken against such over-erased defective memory cell differ from those against defects in a decoder or charge pump circuit. Another problem lies in that failure analysis for improvement wastes time and cost.

### SUMMARY OF THE INVENTION

An object of the present invention is to provide a semiconductor memory incorporating a configuration for distinguishing an over-erased defective memory cell from other defects.

According to a first aspect of the invention, the semiconductor memory includes a plurality of word lines, a plurality of bit lines and a plurality of memory cells, a Y decoder and a disconnecting device. The plurality of memory cells are each connected to one of the plurality of word lines and one of the plurality of bit lines. The Y decoder is configured to drive the plurality of bit lines. The disconnecting device is provided between at least one of the plurality of bit lines and the Y decoder, and is configured to electrically disconnect the at least one of the plurality of bit lines and the Y decoder.

It can easily be distinguished between whether the Y decoder has a defect and whether an over-erased defective memory cell is present.

According to a second aspect of the invention, the semiconductor memory includes a plurality of memory cells, a Y decoder and a charge pump circuit and a port circuit. The plurality of memory cells are each connected to one of a plurality of word lines and one of a plurality of bit lines. The Y decoder is configured to drive the plurality of bit lines. The charge pump circuit and the port circuit are each connected to the Y decoder through a switching circuit.

Output voltage failure and lack of current supply capability of the charge pump circuit can be distinguished from each other, and evaluation of the performance of the charge pump circuit can easily be performed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating a semiconductor memory according to a first preferred embodiment of the present invention;

FIG. 2 is a circuit diagram illustrating a bit line disconnecting transistor according to the first preferred embodiment;

FIG. 3 is a circuit diagram illustrating a semiconductor memory according to a second preferred embodiment of the invention;

FIG. 4 is a circuit diagram illustrating another semiconductor memory including defective modes according to the second preferred embodiment; and

FIG. 5 is a circuit diagram illustrating a semiconductor memory according to a third preferred embodiment of the invention.

### DESCRIPTION OF THE PREFERRED EMBODIMENTS

The present invention will specifically be described in reference to the accompanying drawings illustrating preferred embodiments.

### First Preferred Embodiment

FIG. 1 is a circuit diagram illustrating a semiconductor memory according to a first preferred embodiment of the present invention. The semiconductor memory illustrated in FIG. 1 has a Y decoder 1 and an X decoder 2. The Y decoder 1 is connected to two bit lines 3 and 4, and the X decoder 2 is connected to four word lines 5 to 8. The drain terminals of flash memory cells 9 to 12 are connected in common to the bit line 3. The drain terminals of flash memory cells 13 to 16 are connected in common to the bit line 4. The bit lines 3 and 4 are connected to a sense amplifier for detecting variations in voltage (or current) applied to the bit lines 3 and 4 at the time of readout. In FIG. 1, the sense amplifier is included in the Y decoder 1.

The gate terminals of the flash memory cells 9 and 13 are connected to the word line 5, the gate terminals of the flash memory cells 10 and 14 are connected to the word line 6, the gate terminals of the flash memory cells 11 and 15 are connected to the word line 7, and the gate terminals of the flash memory cells 12 and 16 are connected to the word line 8. Although FIG. 1 illustrates the two bit lines 3, 4, four word lines 5 to 8 and eight flash memory cells 9 to 16, a semiconductor memory is actually provided with bit lines, word lines and flash memory cells in the number in accordance with the memory capacity.

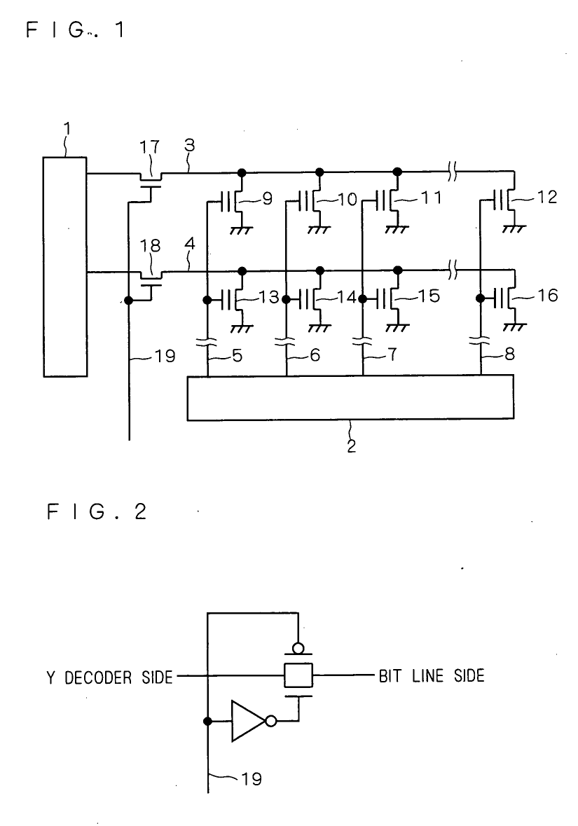

In the present embodiment, bit line disconnecting transistors 17 and 18 serving as disconnecting devices are further provided between the Y decoder 1 and bit lines 3, 4, respectively. The gate terminals of the bit line disconnecting transistors 17 and 18 are connected in common. Although being formed by N channel transistors because of the smallness of layout area and for the purpose of cost reduction, these transistors 17 and 18 are not limited to the N channel transistors but may be formed by other disconnecting devices having similar functions. In the case where P wells are more convenient for area reduction from the point of layout, P channel transistors may be adopted. FIG. 2 illustrates another exemplary configuration of the bit line disconnecting transistors 17 and 18.

In FIG. 1, the bit line disconnecting transistors 17 and 18 are connected to the two bit lines 3 and 4, respectively. That is, the bit line disconnecting transistors 17 and 18 are respectively connected to all the bit lines. However, bit line disconnecting transistors consumes the layout area of a semiconductor memory. Therefore, when miniaturization and high integration is required, the semiconductor memory may be configured in such a manner as to provide a bit line disconnecting transistor only for a bit line if the bit line is found out to be the one on which an over-erased defective memory cell is likely to occur.

In failure analysis, it is distinguished between whether an over-erased defective memory cell is present and whether another defect is present, depending on whether the flash memory cells 9 to 12 on the bit line 3 and flash memory cells 13 to 16 on the bit line 4 are read as being in the written state regardless of the written/erased state of the flash memory cells 9 to 16. That is, a distinction is made depending on whether there is no variation in bit line applied voltage for readout applied to the bit lines 3 and 4. It is easier to understand failure analysis when performed after bringing all the flash memory cells 9 to 16 into the written state in the case where there exists a bit line having all flash memory cells being in the erased state as an expected value. In reading out flash memories, provided that one address corresponds to one bit, the Y decoder 1 selects one of the bit lines 3 and 4 that corresponds to an address value input from an address bus (not shown) and supplies the selected bit line with bit line voltage for readout, while the X decoder 2 selects a corresponding one of the word lines 5 to 8 and supplies the selected word line with word line voltage for readout. Selecting one of the flash memory cells 9 to 16 with the bit lines 3, 4 and word lines 5 to 8, one of the flash memory cells 9 to 16 that corresponds to an address value can be read out. One address is actually comprised of a plurality of bits. In the case of eight bits, for example, the Y decoder 1 selects eight bit lines simultaneously and supplies the selected bit lines with bit line voltage for readout, whereby eight flash memory cells are read out simultaneously.

However, if the flash memory cells 9 to 16 includes an over-erased defective memory cell, leakage current occurs between the source and drain terminals of the over-erased defective memory cell. Thus, a flash memory cell connected to the same bit line as the over-erased defective memory cell, from which current leaks through the over-erased defective memory cell, is also read out as being in the erased state. For instance, when the flash memory cell 9 connected to the bit line 3 is an over-erased defective memory cell, leakage current occurs between the source and drain of the flash memory cell 9 even if the flash memory cells 10 to 12 are in the written state, causing voltage applied to the bit line 3 for readout to be removed. Then, the sense amplifier judges the flash memory cells 10 to 12 to be in the erased state. That is, the flash memory cells 9 to 12 connected to the bit line 3 are all judged to be in the erased state. Likewise, when even one of the flash memory cells 13 to 16 connected to the bit line 4 is an over-erased defective memory cell, the flash memory cells 13 to 16 are all judged to be in the erased state. That is, flash memory cells connected to the same bit line are all judged to be in the erased state contrary to an expected value.

In a similar case of failure in which the bit line 3 or 4 has short-circuit fault with respect to a GND line, voltage applied to the bit line for readout leaks. Then, the sense amplifier judges all flash memory cells connected to the bit line having short-circuit fault with respect to the GND line to be in the erased state. For instance, if the bit line 3 has short-circuit fault with respect to the GND line, the flash memory cells 9 to 12 are judged to be in the erased state. Alternatively, when the bit line 4 has short-circuit fault with respect to the GND line, the flash memory cells 13 to 16 are judged to be in the erased state. That is, flash memory cells connected to the same bit line are all judged to be in the erased state contrary to an expected value.

When the Y decoder 1 has a defect, similar failure occurs as in the case of the over-erased defective memory cell. Here, such defect includes a defect in which the Y decoder 1 cannot appropriately select the bit line 3 or 4, and a defect in which a circuit for selecting the bit line 3 or 4 is shorted to the GND line in a circuit in the Y decoder 1.

Distinguishing an over-erased defective memory cell from a defect in the Y decoder 1 is important in failure analysis. The semiconductor memory according to the present embodiment can easily judge whether the Y decoder 1 has a defect or not. First, when the flash memory cells 9 to 12 connected to the bit line 3 are all read out as being in the erased state contrary to an expected value, or when the flash memory cells 13 to 16 connected to the bit line 4 are all read out as being in the erased state contrary to an expected value, a bit line disconnecting signal 19 is driven LOW and is supplied to the bit line disconnecting transistors 17 and 18, for electrically disconnecting the bit lines 3, 4 integrally from the Y decoder 1. Next, readout is carried out again on memory cells at addresses on the bit line 3 or 4 which has been read out as all being in the erased state contrary to an expected value before disconnection. For instance, when the flash memory cells 9 to 12 connected to the bit line 3 are all judged as being in the erased state contrary to an expected value, one or all of the flash memory cells 9 to 12 connected to the bit line 3 are read out again after disconnection. Likewise, when the flash memory cells 13 to 16 are all judged as being in the erased state contrary to an expected value, one or all of the flash memory cells 13 to 16 are read out again after disconnection.

In the case where the Y decoder 1 is in a normal state and the flash memory cells 9 to 12 connected to the bit line 3 or the flash memory cells 13 to 16 connected to the bit line 4 are all judged to be in the erased state contrary to an expected value, bit line applied voltage for readout does not vary as a matter of course when the Y decoder 1 selects the bit line 3 or 4, since the bit lines 3 and 4 are electrically disconnected from the Y decoder 1. Thus, reading out the bit line 3 or 4 again, the flash memory cells 9 to 12 connected to the bit line 3 or the flash memory cells 13 to 16 connected to the bit line 4 are all read out as being in the written state whether the memory cells 9 to 12 or 13 to 16 are in the written/erased state. In this case, the Y decoder 1 is determined as normal. That is, it shows that leakage current occurs between the source and drain terminals of the over-erased defective memory cell. On the other hand, when readout is carried out again to find out that bit line applied voltage for readout has varied, i.e., when the flash memory cells 9 to 12 or 13 to 16 are read out as being in the erased state after disconnection, the Y decoder 1 is judged as having a defect. That is, it is judged that the Y decoder 1 has a defect which prevents appropriate selection of the bit line 3 or 4, or a defect which causes a circuit for selecting the bit line 3 or 4 to be shorted to the GND line.

As described, since the semiconductor memory according to the present embodiment includes the plurality of flash memory cells 9 to 16 connected to the word lines 5 to 8 and bit lines 3 and 4, the Y decoder 1 for driving the bit lines 3, 4 and the bit line disconnecting transistors 17 and 18 provided between the Y decoder 1 and bit lines 3 and 4, respectively, for electrically disconnecting the bit lines 3 and 4 from the Y decoder 1, it is easily distinguished between whether the Y decoder 1 has a defect and whether an over-erased defective memory cell is present among the flash memory cells 9 to 16.

According to the semiconductor memory of the present embodiment, a semiconductor memory may be formed that is capable of easily judging an over-erased defective memory cell while effectively utilizing the layout area of the semiconductor memory in the case where the bit line disconnecting transistors 17 and 18 are provided only on a bit line where an over-erased defective memory cell is likely to occur.

In the semiconductor memory of the present embodiment, the bit line disconnecting transistors 17 and 18 electrically disconnect the plurality of bit lines 3 and 4 integrally from the Y decoder 1, eliminating the need to separately provide a circuit for controlling the bit line disconnecting transistors 17 and 18, which allows failure analysis to be performed with a simple configuration.

The semiconductor memory of the present embodiment may be used for acceptable product selection test of the Y decoder 1, not for failure analysis. Further, although the present embodiment has described the semiconductor memory as flash memory, the semiconductor memory may be one that is read out by detecting variations in current (voltage) on the bit lines 3 and 4 by a sense amplifier, and includes a mask ROM, for example.

Furthermore, although being provided outside the Y decoder 1 in the present embodiment, the bit line disconnecting transistors 17 and 18 may be provided within the Y decoder 1 separately from the function of selecting/non-selecting the bit lines 3 or 4 only if they have the function of electrically disconnecting the bit lines 3 and 4 from the Y decoder 1. This allows the layout area of the semiconductor memory to be utilized effectively.

### Second Preferred Embodiment

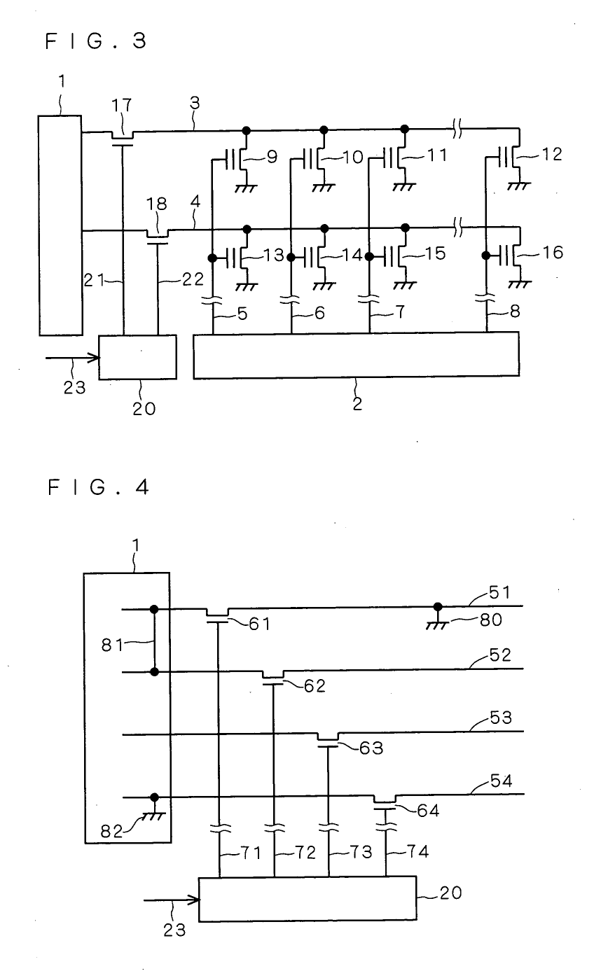

FIG. 3 is a circuit diagram illustrating a semiconductor memory according to the present embodiment. The semiconductor memory illustrated in FIG. 3 has the Y decoder 1 and X decoder 2 as in the first preferred embodiment. The Y decoder 1 is connected to the two bit lines 3 and 4, and the X decoder 2 is connected to the four word lines 5 to 8. The eight flash memory cells 9 to 16 are connected to the bit lines 3, 4 and word lines 5 to 8. The bit lines 3 and 4 are connected to a sense amplifier for detecting variations in voltage (or current) applied to the bit lines at the time of readout. In FIG. 3, the sense amplifier is included in the Y decoder 1. Further, the bit line disconnecting transistors 17 and 18 serving as disconnecting devices are further provided between the Y decoder 1 and bit lines 3 and 4, respectively. Although FIG. 3 also illustrates the two bit lines 3, 4, the four word lines 5 to 8 and eight flash memory cells 9 to 16, a semiconductor memory is actually provided with bit lines, word lines and flash memory cells in the number in accordance with the memory capacity.

In the present embodiment, the gate terminals of the bit line disconnecting transistors 17 and 18 are not connected in common but are connected individually to a disconnection control circuit 20, which is different from the first preferred embodiment. A bit line disconnecting signal 21 sent from the disconnection control circuit 20 to the bit line disconnecting transistor 17 controls ON/OFF of the bit line disconnecting transistor 17. Likewise, a bit line disconnecting signal 22 sent from the disconnection control circuit 20 to the bit line disconnecting transistor 18 controls ON/OFF of the bit line disconnecting transistor 18. By taking a logic value of L or H, an operation instructing signal 23 instructs the disconnection control circuit 20 to start controlling the bit line disconnecting transistors 17 and 18. Although being formed by N channel transistors because of the smallness of layout area and for the purpose of cost reduction, these transistors 17 and 18 are not limited to the N channel transistors but may be formed by other disconnecting devices having similar functions. In the case where P wells are more convenient for area reduction from the point of layout, P channel transistors may be adopted. FIG. 2 illustrates another exemplary configuration of the bit line disconnecting transistors 17 and 18.

Although FIG. 3 illustrates the configuration in which the bit line disconnecting transistors 17 and 18 are individually connected to the disconnection control circuit 20, the gate terminals of the bit line disconnecting transistors 17 and 18 may be connected to the disconnection control circuit 20 each time the bit line disconnecting transistors 17 and 18 are controlled. That is, bit line disconnecting transistors may be integrated on the basis of an arbitrary unit and to be connected to one bit line disconnecting signal and connected to the disconnection control circuit 20. When miniaturization and high integration is required, this configuration allows the number of bit line disconnecting signals controlled by the disconnection control circuit 20 to be reduced, which can simplify the configuration of the disconnection control circuit 20.

Further, In FIG. 3, the bit line disconnecting transistors 17 and 18 are connected to the two bit lines 3 and 4, respectively. That is, the bit line disconnecting transistors 17 and 18 are respectively connected to all the bit lines. However, bit line disconnecting transistors consumes the layout area of a semiconductor memory. Therefore, when miniaturization and high integration is required, the semiconductor memory may be configured in such a manner as to provide a bit line disconnecting transistor only for a bit line if the bit line is found out to be the one on which an over-erased defective memory cell is likely to occur.

In the first preferred embodiment, it can easily be distinguished between whether the Y decoder 1 has a defect and whether an over-erased defective memory cell is present among the flash memory cells 9 to 16. However, the first preferred embodiment can only disconnect both the bit lines 3 and 4 integrally from the Y decoder 1. Thus, when over-erased defective memory cells are present on the bit lines 3 and 4, respectively, i.e., on the plurality of bit lines, respectively, or when the bit lines 3 and 4 are shorted to each other, failure analysis cannot be performed in detail. The present embodiment therefore configures the bit lines 3 and 4 to be individually disconnected from the Y decoder 1, so that failure analysis can be performed in detail in the case where over-erased defective memory cells are present on the plurality of bit lines 3 and 4, respectively.

In the present embodiment, by taking a logic value of L or H, the operation instructing signal 23 drives the disconnection control circuit 20 so as to individually control the bit line disconnecting transistors 17 and 18. The disconnection control circuit 20 sends the bit line disconnecting signals 21 and 22 for turning the bit line disconnecting transistors 17 and 18 ON/OFF to the gate terminals of the bit line disconnecting transistors 17 and 18, respectively.

FIG. 4 is a circuit diagram illustrating a semiconductor memory including defective modes. Failure analysis will specifically be described in reference to FIG. 4. FIG. 4 illustrates the Y decoder 1, four bit lines 51 to 54, bit line disconnecting transistors 61 to 64 and disconnection control circuit 20. The bit line 51 has a ground fault point 80 resulting from an over-erased defective memory cell. This is because leakage current occurs between the source and drain of the over-erased defective memory cell. The ground fault point 80 is also present when the bit line 51 is shorted directly to a GND line similarly to the case of an over-erased defective memory cell. The bit lines 51 and 52 have short-circuit fault with each other in the Y decoder 1. This shorted point is called a mutual short-circuit fault point 81. Further, the bit line 54 has a ground fault point 82 shorted to the GND line in the Y decoder 1.

Driving the semiconductor memory having defects as shown in FIG. 4, flash memory cells connected to the bit lines 51, 52 and 54 are all judged as being in the erased state contrary to an expected value. Thus, failure analysis is performed on the semiconductor memory shown in FIG. 4 by the method described in the first preferred embodiment of disconnecting all the bit lines 51 to 54 integrally from the Y decoder 1. This method can distinguish between the ground fault points 80 and 82 if there only exist the ground fault points 80 and 82. However, with respect to the mutual short-circuit fault point 81, voltage applied to both the bit lines 51 and 52 for readout does not vary when reading out flash memory cells connected to the bit line 51 or 52 as disconnected since the bit lines 51 to 54 are integrally disconnected from the Y decoder 1. Therefore, it is judged that the bit lines 51 and 52 each have the ground fault point 80.

Therefore, the bit line disconnecting transistors 61 and 62 are separately controlled to perform failure analysis as in the present embodiment. A failure analysis method of the present embodiment includes first and second methods. The first method is to control a disconnecting device for electrically disconnecting a bit line and the Y decoder for each bit line, to electrically disconnect a first bit line, and further to read out an address on the first bit line. The second method is to control a disconnecting device for electrically disconnecting a bit line and the Y decoder for each bit line, to electrically disconnect a first bit line, and further to read out an address on a second bit line.

First, failure analysis for the ground fault point 80 can be performed carrying out the first method on the bit line 51. A bit line disconnecting signal 71 is supplied from the disconnection control circuit 20 to control the bit line disconnecting transistor 61, for electrically disconnecting the bit line 51 from the Y decoder 1. Reading out the bit line 51 in this state, the Y decoder 1 is judged to be in a normal operating state since the bit line applied voltage for readout does not vary. On the other hand, when the first method is carried out on the bit line 52 for failure analysis, the bit line 52 is electrically disconnected from the Y decoder 1 for reading out the bit line 52. Then, the bit line applied voltage for readout leaks from the ground fault point 80 through the mutual short-circuit fault point 81. Therefore, the Y decoder 1 is judged to have a defect. This eliminates an erroneous judgment that the bit lines 51 and 52 each have an over-erased defective flash memory cell.

Next, failure analysis for the mutual short-circuit fault point 81 and ground fault point 82 is performed carrying out the first method on the bit lines 52 and 54, which allows the Y decoder 1 to be judged to have a defect. Specifically, a bit line disconnecting signal 72 is supplied from the disconnection control circuit 20 to control the bit line disconnecting transistor 62, for electrically disconnecting the bit line 52 from the Y decoder 1. Reading out the bit line 52 in this state, the bit line applied voltage for readout is judged to leak from the ground fault point 80 through the bit line 51 since the Y decoder 1 has the mutual short-circuit fault point 81. Then, it is judged that current flows from the Y decoder 1 to the bit line 52, and that the Y decoder 1 is in the abnormal state. A bit line disconnecting signal 74 is supplied from the disconnection control circuit 20 to control the bit line disconnecting transistor 64, for electrically disconnecting the bit line 54 from the Y decoder 1. Reading out the bit line 54 in this state, the bit line applied voltage for readout is judged to leak due to the ground fault point 82. Then, it can be judged that the Y decoder 1 is in the abnormal state.

As described, with the use of the first method for failure analysis, it can be judged that the mutual short-circuit fault point 81 or ground fault point 82 is present in the Y decoder 1. However, a defect in the Y decoder 1 cannot be judged as the mutual short-circuit fault point 81 or ground fault point 82 only with the first method. Therefore, failure analysis is performed carrying out the second method for these defective modes.

First, failure analysis is performed for the mutual short-circuit fault point 81. The bit line disconnecting signal 71 is supplied from the disconnection control circuit 20 to control the bit line disconnecting transistor 61, for electrically disconnecting the bit line 51 from the Y decoder 1. Reading out the bit line 52 in this state, it is judged that the bit line applied voltage for readout does not vary since the ground fault point 80 is disconnected by the bit line disconnecting transistor 61, and the Y decoder 1 can be judged to be in the normal operating state (the second method). Likewise, the second method is carried out on the other bit lines 53 and 54. With this failure analysis method, it is judged that the bit line 52 does not have an over-erased defective flash memory cell but has the mutual short-circuit fault point 81. That is, when failure analysis is performed for the mutual short-circuit fault point 81, the first method judges the Y decoder 1 to be in the abnormal state whereas the second method judges the Y decoder 1 to be in the normal state.

On the other hand, failure analysis is performed for the ground fault point 82. The bit line disconnecting signal 71 is supplied from the disconnection control circuit 20 to control the bit line disconnecting transistor 61, for electrically disconnecting the bit line 51 from the Y decoder 1. Reading out the bit line 54 in this state, the bit line applied voltage for readout is judged to leak due to the ground fault point 82. Then, it is judged that the Y decoder 1 is in the abnormal state (the second method). Likewise, the second method is carried out on the other bit lines 52 and 53. That is, when failure analysis is performed for the ground fault point 82, the Y decoder 1 is judged to be in the abnormal state with the first method, and the Y decoder 1 is also judged abnormal with the second method. This shows that a ground fault point is not present on the bit line 54 but is present within the Y decoder 1.

By combining the above-described first and second methods for failure analysis, a distinction can be made between the ground fault point 80 which is an over-erased defective flash memory cell, the mutual short-circuit fault point 81 in the Y decoder 1 and the ground fault point 82 in the Y decoder 1.

As described, in the semiconductor memory according to the present embodiment, the bit line disconnecting transistors 17, 18 and 61 to 64 can electrically disconnect the plurality of bit lines 3, 4 and 51 to 54 individually from the Y decoder 1. Thus, failure analysis can easily be performed even if the semiconductor memory includes defective modes other than an over-erased defective memory cell.

Further, the method of distinguishing defects in a semiconductor memory according to the present embodiment is a method including a step of electrically disconnecting a first one of the bit lines 51 to 54 from the Y decoder 1 and a step of reading out an address on the first one of the bit lines 51 to 54, or a method including a step of reading out an address on a second one of the bit lines 51 to 54 instead of the step of reading out an address on the first one of the bit lines 51 to 54, or combination of these methods. Thus, various defective modes including an over-erased defective memory cell and a defect in a decoder can be distinguished from each other.

In the semiconductor memory according to the present embodiment, the bit line disconnecting transistors 17, 18 and 61 to 64 may be used for acceptable product selection test of the Y decoder 1, not for failure analysis. Further, although the present embodiment has described the semiconductor memory as flash memory, the semiconductor memory may be one that is read out by detecting variations in current (voltage) on the bit lines 3, 4 and 51 to 54 by a sense amplifier, and includes a mask ROM, for example.

Furthermore, although being provided outside the Y decoder 1 in the present embodiment, the bit line disconnecting transistors 17, 18 and 61 to 64 may be provided within the Y decoder 1 separately from the function of selecting/non-selecting the bit lines 3, 4 51 to 54 only if they have the function of electrically disconnecting the bit lines 3, 4 and 51 to 54 from the Y decoder 1. This allows the layout area of the semiconductor memory to be utilized effectively.

### Third Preferred Embodiment

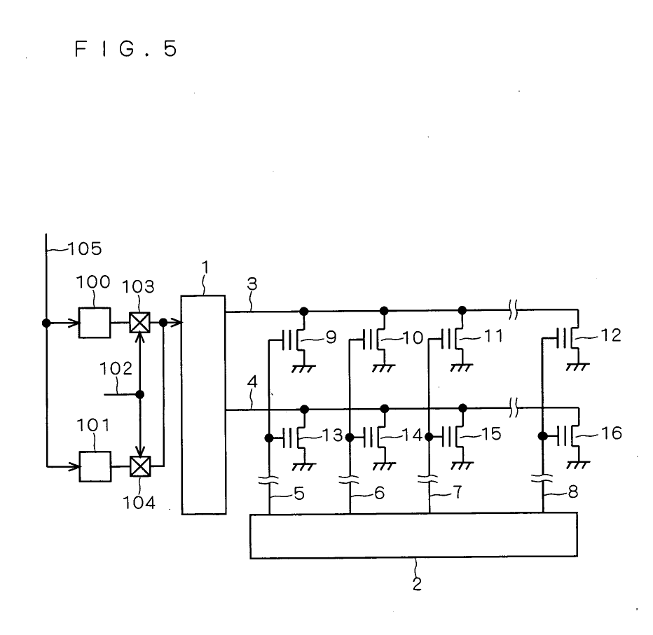

FIG. 5 is a circuit diagram illustrating a semiconductor memory according to present embodiment of the present invention. The semiconductor memory illustrated in FIG. 5 has the Y decoder 1 and X decoder 2 as in the first preferred embodiment. The Y decoder 1 is connected to the two bit lines 3 and 4, and the X decoder 2 is connected to the four word lines 5 to 8. The eight flash memory cells 9 to 16 are respectively connected to one of the bit lines 3 and 4 and one of the word lines 5 to 8. The bit lines 3 and 4 are connected to a sense amplifier for detecting variations in voltage (or current) applied to the bit lines 3, 4 at the time of readout. In FIG. 5, the sense amplifier is included in the Y decoder 1. Although FIG. 5 illustrates the two bit lines 3, 4, four word lines 5 to 8 and eight flash memory cells 9 to 16, a semiconductor memory is actually provided with bit lines, word lines and flash memory cells in the number in accordance with the memory capacity.

In the present embodiment, a port circuit 101 capable of supplying voltage to the Y decoder 1 from outside is provided separately from a charge pump circuit 100 connected to the Y decoder 1. The charge pump circuit 100 includes a switching circuit 103 controlled by a switching signal 102, and the port circuit 101 includes a switching circuit 104 also controlled by the switching signal 102. The switching circuits 103 and 104 may be integrated into one switching circuit.

When the semiconductor memory illustrated in FIG. 5 operates normally, a charge pump activating signal 105 is supplied to the charge pump circuit 100, and voltage for writing is applied to the Y decoder 1 from the charge pump circuit 100 through the switching circuit 103. Accordingly, the Y decoder 1 can apply the voltage for writing from the charge pump circuit 100 to the bit line 3 or 4 to perform writing to the flash memory cells 9 to 12 or 13 to 16. However, when the charge pump circuit 100 has output voltage failure or lacks the current supplying capability, the voltage for writing from the charge pump circuit 100 is not sufficiently applied to the Y decoder 1, which prevents the Y decoder 1 to perform writing to the flash memory cells 9 to 12 or 13 to 16. Thus, addresses on the bit line 3 or 4 may be read out to be in the erased state since writing to the flash memory cells 9 to 12 or 13 to 16 has not sufficiently been performed. This state is the same as that in which the bit line 3 or 4 has an over-erased defective memory cell. Thus, a defect in the charge pump circuit 100 and an over-erased defective flash memory cell cannot be distinguished from each other in failure analysis.

Therefore, the present embodiment configures the semiconductor memory such that voltage for writing can also be applied to the Y decoder 1 from the port circuit 101 as well as the charge pump circuit 100 in order for distinguishing between a defect in the charge pump circuit 100 and an over-erased defective flash memory cell. Hereinbelow, the failure analysis method according to the present embodiment will specifically be described. First, when the semiconductor memory operates normally, the switching circuits 103 and 104 are controlled by the switching signal 102 to electrically connect the charge pump circuit 100 and Y decoder 1 and to electrically disconnect the port circuit 101 and Y decoder 1. Next, in failure analysis of the charge pump circuit 100, the switching circuits 103 and 104 are controlled by the switching signal 102 to electrically disconnect the charge pump circuit 100 and Y decoder 1 and to electrically connect the port circuit 101 and Y decoder 1. An external source (not shown) is connected to the port circuit 101 from outside the semiconductor device, and voltage supplied from the external source is applied to the Y decoder 1. Note that the port circuit 101 applies the external supply voltage to the Y decoder 1 only when the charge pump activating signal 105 is supplied thereto.

Accordingly, in the case where writing to the flash memory cells 9 to 12 on the bit line 3 or the flash memory cells 13 to 16 on the bit line 4 can be performed with an external potential from the external supply through the port circuit 101, it can be judged that the charge pump circuit 100 has output voltage failure or lacks the current supply capability. That is, a defect in the charge pump circuit 100 can be distinguished by detecting whether or not writing can be performed with the external potential from the external supply to the bit line 3 or 4 to which writing cannot be performed by a normal operation. Conversely, in the case where the flash memory cells 9 to 16 on the bit line 3 and 4 are judged to be in the erased state when the semiconductor memory operates normally and where the flash memory cells 9 to 16 on the bit line 3 and 4 are judged to be in the erased state in failure analysis of the charge pump circuit 100, it is judged that an over-erased defective flash memory cell is present.

The semiconductor memory illustrated in FIG. 5 may be used for evaluating, as initial evaluation, output voltage or current supply capability of the charge pump circuit 100 necessary for writing by means of voltage/current applied to the port circuit 101, rather than for failure analysis. Further, the present embodiment has been directed to writing to the flash memory cells 9 to 16, however, in a semiconductor memory which supplies output voltage of the charge pump circuit 100 to the Y decoder 1 in other operations such as erasure and readout, output voltage failure or lack of current supply capability of the charge pump circuit 100 in other operations may also be distinguished.

Furthermore, the semiconductor memory according to the first preferred embodiment and that of the second preferred embodiment may be combined together to form a semiconductor memory capable of distinguishing between various defective modes. That is, such semiconductor memory includes the bit line disconnecting transistors 17, 18 and disconnection control circuit 20 in addition to the port circuit 101.

With the method of distinguishing defects of the semiconductor memory according to the present embodiment, the port circuit 101 is connected to the external source to supply voltage for writing or voltage for erasure to the bit line 3 and 4. Thus, output voltage failure and lack of current supply capability of the charge pump circuit 100 can easily be distinguished from each other.

Further, the semiconductor memory according to the present embodiment is formed by combining the semiconductor memory including the bit line disconnecting transistors 17, 18 and disconnection control circuit 20 and that including the port circuit 101. Thus, various defective modes can easily be distinguished.

Next, a semiconductor memory according to a variant of the present embodiment will be described. In the semiconductor memory of this variant, the charge pump circuit 100 and Y decoder 1 are electrically connected and the port circuit 101 and Y decoder 1 are electrically connected by the switching signal 102. In the semiconductor memory of such configuration, output voltage of the charge pump circuit 100 at the time of writing can be measured by connecting a measuring device (not shown) instead of the external supply to the port circuit 101.

With the method of distinguishing defects of the semiconductor memory according to the variant of the present embodiment, the port circuit 101 is connected to the measuring device for measuring output voltage of the charge pump circuit 100 connected to the Y decoder 1. Thus, the capability of the charge pump circuit 100 can easily be measured only by connecting the measuring device to the port circuit 101.

In the semiconductor memory according to the present embodiment, the bit line disconnecting transistors 17, 18 and 61 to 64 may be used for acceptable product selection test of the Y decoder 1, rather than for failure analysis. Further, although the present embodiment has described the semiconductor memory as flash memory, the semiconductor memory may be one that is read out by detecting variations in current (voltage) on the bit lines 3, 4 and 51 to 54 by a sense amplifier, and includes a mask ROM, for example.

While the invention has been shown and described in detail, the foregoing description is in all aspects illustrative and not restrictive. It is therefore understood that numerous modifications and variations can be devised without departing from the scope of the invention.

What is claimed is:

1. A semiconductor memory comprising:
a plurality of word lines, a plurality of bit lines and a plurality of memory cells, said plurality of memory cells each being connected to one of said plurality of word lines and one of said plurality of bit lines;
a Y decoder configured to drive said plurality of bit lines; and
a disconnecting device provided between at least one of said plurality of bit lines and said Y decoder, and being configured to electrically disconnect said at least one of said plurality of bit lines and said Y decoder.

2. The semiconductor memory according to claim 1, wherein
said disconnecting device includes a plurality of disconnecting devices, capable of electrically disconnecting those of said plurality of bit lines on which said plurality of disconnecting devices are provided integrally from said Y decoder.

3. The semiconductor memory according to claim 1, wherein
said disconnecting device includes a plurality of disconnecting devices, capable of electrically disconnecting those of said plurality of bit lines on which said plurality of disconnecting devices are provided individually from said Y decoder.

4. A semiconductor memory comprising:
a plurality of memory cells, each being connected to one of a plurality of word lines and one of a plurality of bit lines;
a Y decoder configured to drive said plurality of bit lines; and
a charge pump circuit and a port circuit, each being connected to said Y decoder through a switching circuit.
